(19) United States
(12) Patent Application Publication
(10) Pub. No.: US 2009/0129525 A1
(43) Pub. Date: May 21, 2009

(54) APPARATUS AND METHOD FOR PHASE LOCKED LOOP

(76) Inventor: Tae Young OH, Seoul (KR)

Correspondence Address: BIRCH STEWART KOLASCH & BIRCH, PO BOX 747, FALLS CHURCH, VA, 22040-0747, US

(21) Appl. No.: 11/945,821

(22) Filed: Nov. 27, 2007

(30) Foreign Application Priority Data
Nov. 16, 2007 (KR) 10-2007-0117093

(51) Int. Cl. H03D 3/24

(52) U.S. Cl. 375/376

(57) ABSTRACT

The PLL (Phase Locked Loop) apparatus and the PLL method are disclosed, wherein an output clock signal is counted in response to a reference clock signal to detect a frequency offset value and divide the output clock signal by a prescribed value to generate a phase detection value in response to the reference clock signal, generating a frequency error value to adjust a frequency of the output clock signal if the frequency offset value is not between a prescribed frequency offset maximum value and a predetermined frequency offset minimum value, and generating a phase error value in response to the phase detection value to adjust a phase of the output clock signal if the frequency offset value is in between a prescribed frequency offset maximum value and a prescribed frequency offset minimum value.

### CROSS-REFERENCE TO RELATED APPLICATION

The present application is based on, and claims priority from, Korean Application Numbers 10-2007-0117093 filed Nov. 16, 2007, the disclosure of which is incorporated herein by reference in its entirety.

### BACKGROUND

The following description relates generally to an apparatus and method for phase locked loop.

In general, an apparatus for phase locked loop (PLL) (hereinafter referred to as PLL apparatus) widely used in various applications, such as, communication systems and household electronic products employs a negative feedback loop to reduce a phase difference between an input signal and an output signal or to eliminate the difference.

If the PLL apparatus is realized by an analog circuit, the circuit is not stably operated due to changes of operating condition, i.e., fabrication variation of semiconductor devices, temperature and voltage changes. Another shortcoming is that the analog PLL apparatus is larger than a digital PLL apparatus.

For that reason, a digital PLL apparatus is widely used lately. The known digital PLL apparatus typically includes an apparatus for sampling a reference clock signal and feedback clock signal by a high time resolution using a high speed clock signal and counter, and a detector for detecting a phase error value by sampling a count value of a feedback divider.

The apparatus for sampling the reference clock signal and the feedback clock signal uses a high frequency of clock signal and counter to make the PLL apparatus bulky and susceptible to high consumption of electricity. Therefore, unless a high precision is required, a digital PLL apparatus is largely employed for detecting a phase error value by sampling a count value of the feedback divider.

### SUMMARY

However; there are cases where the digital PLL apparatus for detecting a phase error value by sampling the count value of the feedback divider cannot cause an output clock signal to be locked to a reference clock signal in response to an initial value of a digital loop filter.

The present inventive concept may therefore provide an apparatus for PLL (Phase Locked Loop) apparatus and method (hereinafter referred to as PLL apparatus and PLL method) capable of causing an output clock signal to be precisely locked to a reference clock signal.

The concept may also provide a PLL apparatus and a PLL method capable of causing an output clock signal to be instantly locked to a reference clock signal without recourse to initializing a digital loop filter even if frequency of the reference clock signal is suddenly changed.

According to the PPL apparatus and PLL method, an output clock signal is counted in response to a reference clock signal to detect a frequency offset value. The output clock signal is divided by a predetermined value to detect a phase detection value, and the detected phase detection value is outputted in response to the reference clock signal.

The frequency offset value is compared with a prescribed frequency offset maximum value and a prescribed frequency offset minimum value. As a result of the comparison, if the frequency offset value is not between the frequency offset maximum value and the frequency offset minimum value, the phase detection value is disregarded, and a phase error value is generated in response to the frequency offset value to adjust a frequency of the output clock signal.

As a result of the comparison, if the frequency offset value is between the frequency offset maximum value and the frequency offset minimum value, a phase error value is generated in response to the phase detection value to adjust a phase of the output clock signal.

In one general aspect, a PLL (Phase Locked Loop) apparatus comprises: a frequency/phase detector for detecting a frequency and a phase of an output clock signal in response to a reference clock signal; an encoder for generating a phase error value in response to the frequency and phase detected by the frequency/phase detector; a digital loop filter for filtering the phase error value generated by the encoder; and a DCO (Digitally Controlled Oscillator) for generating the output clock signal in response to an output signal of the digital loop filter.

Implementations of this aspect may include one or more of the following features.

The frequency/phase detection unit comprises: a counter for counting the output clock signal responsive to the reference clock signal to output a frequency offset value; and a feedback divider for counting and dividing the output clock signal and for outputting the divided value as a phase detection value responsive to the reference clock signal.

The encoder outputs to the digital loop filter a frequency increment value or a frequency decrement value in response to the frequency offset value if the frequency offset value is not between a prescribed frequency offset maximum value and a prescribed frequency offset minimum value, and outputs to the digital loop filter a phase error value in response to the phase detection value if the frequency offset value is between a prescribed frequency offset maximum value and a prescribed frequency offset minimum value.

The phase error value based on the phase detection value is operated in such a fashion that if the phase detection value is less than N/2 (N is a maximum count value of a feedback divider generated by the phase detection value), a phase error value of “−phase detection value−1” is generated, and the phase detection value is not less than N/2, a phase error value of “N−phase detection value” is generated.

In another general aspect, a PLL (Phase Locked Loop) method comprises: counting, by a counter, an output clock signal generated by a DCO (Digitally Controlled Oscillator) in response to a reference clock signal to output a frequency offset value, and counting and dividing, by a feedback divider, the output clock signal to output a division value as a phase detection value in response to the reference clock signal; generating, by an encoder, a frequency increment value or a frequency decrement value if the frequency offset value is not between a prescribed frequency offset maximum value and a predetermined frequency offset minimum value to adjust a frequency of the output clock signal generated by the DCO; and generating, by the encoder, a phase error value in response to the phase detection value if the frequency offset value is between a prescribed frequency offset maximum value and a prescribed frequency offset minimum value to adjust a phase of the output clock signal generated by the DCO.

Implementations of this aspect may include one or more of the following features.

The encoder generates the frequency decrement value if the frequency offset value is greater than the frequency offset maximum value.

The encoder generates the frequency increment value if the frequency offset value is smaller than the frequency offset minimum value.

The generation of phase error value based on the phase detection value comprises: comparing the phase detection value with N/2 (N is a maximum count value of a feedback divider generated by the phase detection value); generating a phase error value of “−phase detection value−1” if the phase detection value is less than N/2 as a result of the comparison; and generating a phase error value of “N−phase detection value” if the phase detection value is not less than N/2.

### BRIEF DESCRIPTION OF THE DRAWINGS

The method, apparatus, and other implementations not to be considered as limiting the novel concept will be better understood from a consideration of the following description in conjunction with the drawings in which like reference numerals identifying correspondingly throughout are carried forward.

FIG. 1 is a block diagram illustrating a configuration of a PLL apparatus detecting a phase error value by sampling a feedback divider value.

FIGS. 2a and 2b are schematic drawings illustrating errors generated by a PLL apparatus sampling a feedback divider value.

FIG. 3 is a block diagram illustrating a configuration of a PLL apparatus according to an exemplary implementation.

FIGS. 4, 5 and 6 are waveform drawings illustrating an operation of a PLL apparatus.

FIG. 7 is a signal flowchart illustrating a PLL method.

### DETAILED DESCRIPTION

The following paragraphs are nothing but exemplars that explain the principles of the novel concept. As will be recognized by those skilled in the art, the innovative concept described in the present application can be modified and varied over a tremendous range of applications, and accordingly the scope of patented subject matter is not limited by any of the specific exemplary teachings given. For the purpose of clarity, technical material that is known in the technical fields related to the invention has not been described in detail so that the concept is not unnecessarily obscured.

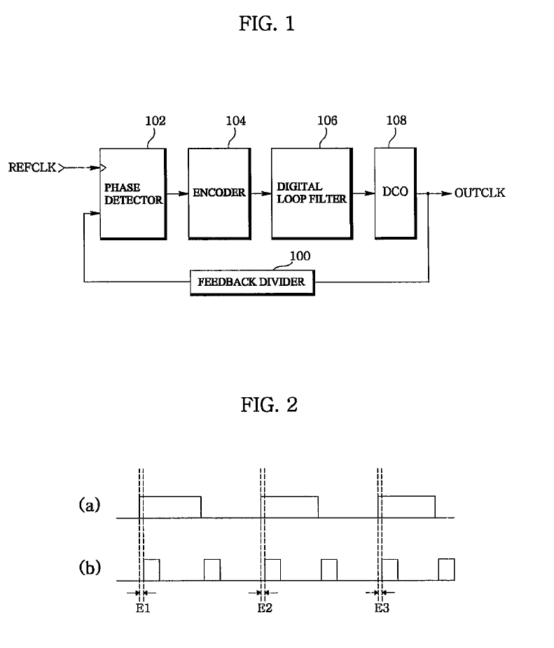

FIG. 1 is a block diagram illustrating a configuration of a PLL apparatus for detecting a phase error value by sampling a feedback divider value, where reference numeral 100 denotes a feedback divider. The feedback divider (100) may divide an output clock signal (OUTCLK) outputted to outside by a PLL apparatus by repeated counts as much as a prescribed value.

The output clock signal outputted by the feedback divider (100) may be inputted to a phase detector (102). A clock terminal of the phase detector (102) may be inputted by a reference clock signal (REFCLK). Thereby, the phase detector (102) may sample a count value of the feedback divider (100) by the phase detection value and store if the phase detector (102) is at the rising edge of the reference clock signal (REFCLK). The phase detection value stored by the phase detector (102) may be inputted into an encoder (104). The encoder (104) may determine whether the phase detection value inputted from the phase detector (102) is less than N/2, where, N denotes a maximum count value of the feedback divider (100). As a result of the determination, if the phase detection value inputted from the phase detector (102) is less than N/2, a phase error value may be generated as shown in Equation 1.

Phase error value=−phase detection value−1, [Equation 1]

where, the reason of deducting 1 when the phase detection value is less than N/2 is to remove a dead zone where a phase detection output is zero.

If the phase detection value inputted from the phase detector (102) is not less than N/2, a phase error value may be generated as shown in Equation 2.

Phase error value=N−phase detection value [Equation 2]

The phase error value generated by the encoder (104) may be inputted into a digital loop filter (106) and filtered. An output signal of the digital loop filter (106) may be inputted into a DCO (Digitally Controlled Oscillator. 108), where the DCO (108) may generate an output clock signal (OUTCLK) in response to the output signal from the digital loop filter (106).

In the PLL apparatus, the output clock signal (OUTCLK) must be locked to the reference clock signal. However, there are cases where the output clock signal (OUTCLK) is not locked to the reference clock signal (REFCLK) in response to an initial value of the digital loop filter (106).

For example, FIG. 2a illustrates a reference clock signal (REFCLK), and FIG. 2b illustrates an output clock signal (OUTCLK) having a frequency twice that of the reference clock signal (REFCLK). Under this circumstance, because the frequency of the output clock signal is twice that of the reference clock signal, a control value outputted from the digital loop filter must decrease to allow the output clock signal (OUTCLK) to be locked to the reference clock signal.

However, because phase error values (E1, E2, E3) that are to be detected are all positive values, the control value outputted from the digital loop filter may be outputted in an increasing direction. As a result, an error may occur where the output clock signal (OUTCLK) is not locked to the reference clock signal.

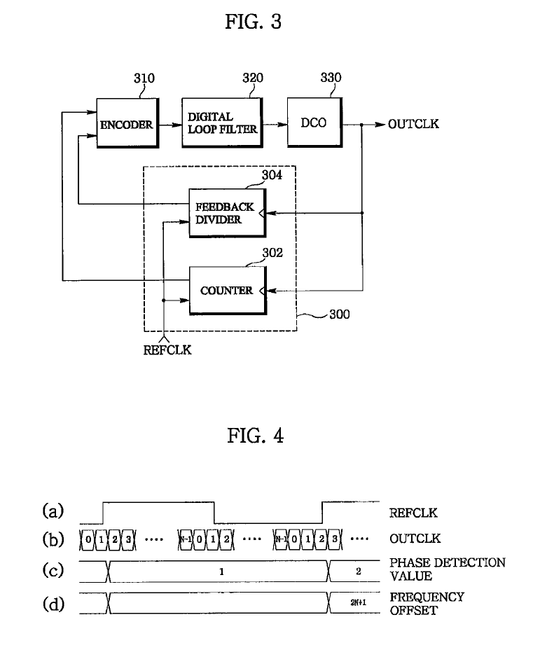

FIG. 3 is a block diagram illustrating a configuration of a PLL apparatus according to an exemplary implementation, where reference numeral 300 defines a frequency/phase detection unit for detecting frequency and phase of the output clock signal (OUTCLK) responsive to the reference clock signal (REFCLK). The frequency/phase detection unit (300) includes a counter (302) and a feedback divider (304). The counter (302) may count the output clock signal (OUTCLK) in response to the reference clock signal (REFCLK). In other words, the counter (304) may be initialized to start counting the output clock signal (OUTCLK) when the reference clock signal (REFCLK) is inputted. When the reference clock signal (REFCLK) is inputted again, a count value of the output clock signal (OUTCLK) counted so far may be outputted to an encoder (310), and the counter may be initialized to repeat the operation of recounting the output clock signal (OUTCLK).

The feedback divider (304) may repeatedly count the output clock signal (OUTCLK) as much as a prescribed value and divide, and the divided count value may be outputted to the encoder (310) in response to the reference clock signal (REFCLK).

The encoder (304) may input the count value of the counter (304) as a frequency offset value, where the inputted frequency offset value may be compared with a prescribed frequency offset maximum value and a prescribe frequency offset minimum value.

As a result of the comparison, if the frequency offset value is greater than the prescribed frequency offset maximum value, it denotes that the frequency of the output clock signal is greater than that of the reference clock signal (REFCLK), where the encoder (310) may generate a frequency decrement value based on a phase error value.

As a result of the comparison, if the frequency offset value is greater than the prescribed frequency offset minimum value, it denotes that the frequency of the output clock signal is smaller than that of the reference clock signal (REFCLK), where the encoder (310) may generate a frequency increment value based on a phase error value.

As a result of the comparison, if the frequency offset value is smaller than the prescribed frequency offset maximum value, but greater than the frequency offset minimum value, it is determined that the frequency of the output clock signal (OUTCLK) matches that of the reference clock signal (REFCLK).

As noted above, if it is determined that the frequency of the output clock signal (OUTCLK) matches that of the reference clock signal (REFCLK), the encoder (310) may receive an output signal of the feedback divider (304) as a phase detection value.

Furthermore, the encoder (310) may determine whether the received phase detection value is less than N/2, where N is a maximum count value of the feedback divider (304). As a result of the determination, if the received phase detection value is less than N/2, a phase error value may be generated as shown in Equation 1.

As a result of the determination, if the received phase detection value is not less than N/2, a phase error value may be generated as shown in Equation 2.

As described above, the phase error value generated by the encoder (310) is inputted into a digital loop filter (320) and filtered thereby. The phase error value filtered by the digital loop filter (320) is inputted into a DCO (Digitally Controlled Oscillator. 330), where the DCO (330) may generate an output clock signal (OUTCLK) locked to the reference clock signal (REFCLK) according to the output signal of the digital loop filter (106).

Now, the PLL apparatus and PLL method will be described in detail with reference to FIGS. 4, 5 and 6.

FIGS. 4a and 4b illustrate a case where a frequency of output signal of the feedback divider (304) dividing the output clock signal (OUTCLK) is twice that of the reference clock signal (REFCLK). Under this circumstance, the feedback divider (304) may output ‘2’ as a phase detection value as shown in FIG. 4c in response to the reference clock signal (REFCLK), and the counter (302) may output ‘2N+1’ as a frequency offset value as illustrated in FIG. 4d. The ‘2N+1’ outputted by the counter (302) is twice the maximum division value of ‘N’ of the feedback divider (304).

As noted above, if the frequency offset value of ‘2N+1’ outputted by the counter (302) is greater than the maximum division value of ‘N’ from the feedback divider (304), the encoder (310) may disregard the phase detection value outputted by the feedback divider (304), and may continuously output to the digital loop filter (320) a frequency decrement value as a phase error value in response to the frequency offset value of ‘2N+1’ outputted by the counter (302). In doing so, the DCO (330) may generate a decreased frequency of the output clock signal (OUTCLK) responsive to the outputted frequency decrement value.

FIGS. 5a and 5b illustrate a case where a frequency of the output signal from the feedback divider (304) dividing the output clock signal (OUTCLK) is lower than that of the reference clock signal (REFCLK). Under this circumstance, the feedback divider (304) may output ‘7’ as a phase detection value as illustrated in FIG. 5c in response to the reference clock signal (REFCLK), and the counter (302) may output ‘6’ as a frequency offset value as depicted in FIG. 5d.

In other words, FIG. 5 is an exemplary implementation illustrating that the counter (302) outputs ‘6’ frequency offset values during a period of the reference clock signal (REFCLK), where ‘6’ is much smaller than ‘N’ of the maximum division value.

Under this circumstance, the encoder (310) may disregard the phase detection value outputted by the feedback divider (304), and may continuously output to the digital loop filter (320) a frequency increment value as a phase error value in response to the frequency offset value of ‘6’ outputted by the counter (302). The DCO (330) may then generate an increase frequency of the output clock signal (OUTCLK) in response to the outputted frequency increment value.

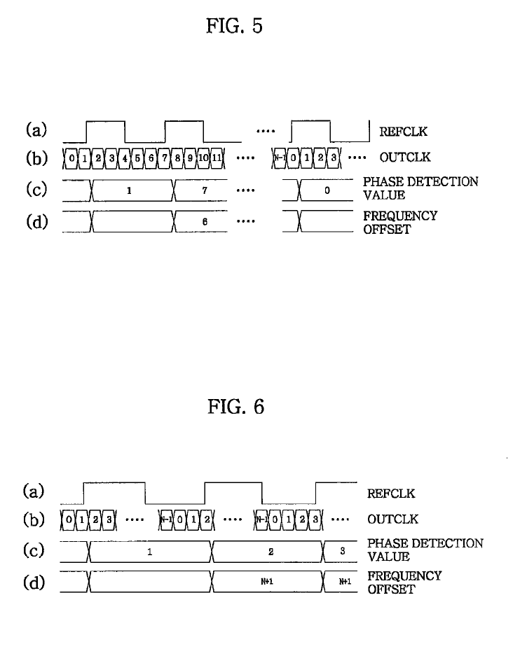

FIGS. 6a and 6b illustrate a case where there is no great difference between a frequency of the output signal of the feedback divider (304) dividing the output clock signal (OUTCLK) and a frequency of the reference clock signal (REFCLK). FIG. 6 is an exemplary implementation illustrating the feedback divider (304) having a counter value of ‘0˜N−1’. In other words, the feedback divider (304) is designed to divide the output clock signal (OUTCLK) by N.

The feedback divider (304) may output ‘N+1’ as a phase detection value as illustrated in FIG. 6d during a period of the reference clock signal (REFCLK) of FIG. 6c. The phase detection value of ‘N+1’ has no great difference from the maximum division value of ‘N’ of the feedback divider (304).

Under this circumstance, the encoder (310) may disregard the frequency offset value outputted by the counter (302), and may generate a phase error value based on the Equation 1 or 2 as a phase detection value outputted by the feedback divider (304) as in the prior art, and output the phase error value to the digital loop filter (320).

Successively, the DCO (330) may change the frequency of the output clock signal (OUTCLK) in response to the phase error value to cause the output clock signal (OUTCLK) to be locked to the reference clock signal (REFCLK).

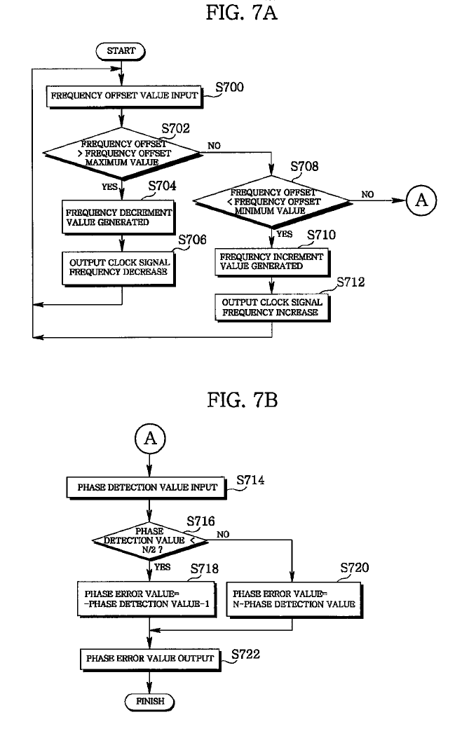

FIGS. 7a and 7b are signal flowcharts illustrating a PLL method.

Referring to FIG. 7a, the counter (302) may count the output clock signal (OUTCLK) to detect a frequency offset value, and may output the detected offset value in response to the reference clock signal (REFCLK), where the encoder (310) may receive the detected frequency offset value (S700).

The encoder (310) may compare the received frequency offset value with a prescribed frequency offset maximum value (S702). As a result of the comparison, if the received frequency offset value is greater than the prescribed frequency offset maximum value, the encoder (310) may generate a frequency decrement value and output the frequency decrement value to the digital loop filter (320) (S704). Thereafter, the DCO (330) may generate a decreased frequency of the output clock signal (OUTCLK) in response to the frequency decrement value (S706).

As a result of the comparison (S702), if the received frequency offset value is not greater than the prescribed frequency offset maximum value, the encoder (310) may compare the frequency offset value with the prescribed frequency offset minimum value (S708). As a result of the comparison, if the received frequency offset value is smaller than the prescribed frequency offset minimum value, the encoder (310) may generate a frequency increment value and output the frequency increment value to the digital loop filter (320)(S710). Thereafter, the DCO (330) may generate an increased frequency of the output clock signal (OUTCLK) in response to the frequency increment value (S712).

Under this circumstance, if the frequency offset value is smaller than the prescribed frequency offset maximum value, but greater than the prescribed frequency offset minimum value, the encoder (310) may receive a phase detection value counted by the feedback divider (304) as depicted in FIG. 7b (S714). Successively, the encoder (310) may compare the received phase detection value with N/2 (S716).

As a result of the comparison, if the phase detection value is greater than N/2, the encoder (310) may calculate a phase error value based on the Equation 1 (S718). As a result of the comparison, if the phase detection value is smaller than N/2, the encoder (310) may calculate the phase error value based on the Equation 2 (S720).

If the phase error value is calculated, the encoder (310) may output the calculated phase error value to the digital loop filter (320) (S722). Thereafter, the DCO (330) may adjust the frequency of the output clock signal (OUTCLK) in response to the phase error value to cause the output clock signal (OUTCLK) to be locked to the reference clock signal (REFCLK).

As apparent from the foregoing, a phase difference between a received reference clock signal and a feedback output clock signal as well as a frequency difference may be detected to allow the output clock signal to be locked to the reference clock signal, whereby the output clock signal may be instantly locked by the changed frequency without recourse to initialization of a digital loop filter when a frequency of the reference clock signal is suddenly changed.

Furthermore, an output clock signal may be stably generated even if there is generated a user's mistake, because there is no need of tabling of an adequate initial value of a digital loop filter whenever the PLL apparatus is operated. The PLL apparatus may be easily used for a frequency mode that is not prescribed.

As is understood by a person skilled in the art, the foregoing exemplary implementations of the present novel concept are illustrative rather than limiting of the present concept. It is intended that they cover various modifications and similar arrangements be included within the spirit and scope of the appended claims, the scope of which should be accorded the broadest interpretation so as to encompass all such modifications and similar structure.

What is claimed is:

1. A PLL (Phase Locked Loop) apparatus, comprising: a frequency/phase detector for detecting a frequency and a phase of an output clock signal in response to a reference clock signal; an encoder for generating a phase error value in response to the frequency and phase detected by the frequency/phase detector; a digital loop filter for filtering the phase error value generated by the encoder; and a DCO (Digitally Controlled Oscillator) for generating the output clock signal in response to an output signal of the digital loop filter.

2. The apparatus as claimed in claim 1, wherein the frequency/phase detector comprises: a counter for counting the output clock signal responsive to the reference clock signal to output a frequency offset value; and a feedback divider for counting and dividing the output clock signal and for outputting the division value as a phase detection value responsive to the reference clock signal.

3. The apparatus as claimed in claim 1, wherein the encoder outputs to the digital loop filter a frequency increment value or a frequency decrement value in response to the frequency offset value if the frequency offset value is not in between a prescribed frequency offset maximum value and a prescribed frequency offset minimum value, and outputs to the digital loop filter a phase error value in response to the phase detection value if the frequency offset value is between a prescribed frequency offset maximum value and a prescribed frequency offset minimum value.

4. The apparatus as claimed in claim 3, wherein the phase error value based on the phase detection value is operated in such a fashion that, if the phase detection value is less than N/2 (N is a maximum count value of a feedback divider generated by the phase detection value), a phase error value of “−phase detection value−1” is generated, and the phase detection value is not less than N/2, a phase error value of “N−phase detection value” is generated.

5. A PLL (Phase Locked Loop) method, comprising: counting, by a counter, an output clock signal generated by a DCO (Digitally Controlled Oscillator) in response to a reference clock signal to output a frequency offset value, and counting and dividing, by a feedback divider, the output clock signal to output a division value as a phase detection value in response to the reference clock signal; generating, by an encoder, a frequency increment value or a frequency decrement value if the frequency offset value is not between a prescribed frequency offset maximum value and a predetermined frequency offset minimum value to adjust a frequency of the output clock signal generated by the DCO; and generating, by the encoder, a phase error value in response to the phase detection value if the frequency offset value is in between a prescribed frequency offset maximum value and a prescribed frequency offset minimum value to adjust a phase of the output clock signal generated by the DCO.

6. The method as claimed in claim 5, wherein the encoder generates the frequency decrement value if the frequency offset value is greater than the frequency offset maximum value.

7. The method as claimed in claim 5, wherein the encoder generates the frequency increment value if the frequency offset value is smaller than the frequency offset minimum value.

8. The method as claimed in claim 5, wherein the generation of phase error value based on the phase detection value comprises: comparing the phase detection value with N/2 (N is a maximum count value of a feedback divider generated by the phase detection value); generating a phase error value of “−phase detection value−1” if the phase detection value is less than N/2 as a result of the comparison; and generating a phase error value of “N−phase detection value” if the phase detection value is not less than N/2.
